(19) United States
(12) Patent Application Publication
(10) Pub. No.: US 2026/0098889 A1
(43) Pub. Date: Apr. 9, 2026

(54) HIGH IMPEDANCE FAULT LOCATION IN ELECTRIC POWER DISTRIBUTION SYSTEMS

(71) Applicant: Eaton Intelligent Power Limited, Dublin 4 (IE)

(72) Inventors: Xiangying MENG, Troy, MI (US); Souvik CHANDRA, Littleton, CO (US); Soumyabrata TALUKDER, Littleton, CO (US); Jinan ZHANG, Lakewood, CO (US); Dmitry ISHCHENKO, Cary, NC (US); Michael NOWAK, Milwaukee, WI (US)

(21) Appl. No.: 18/907,015

(22) Filed: Oct. 4, 2024

(51) Int. Cl. G01R 31/08

(52) U.S. Cl. CPC G01R 31/086; G01R 31/088

(57) ABSTRACT

A method for locating a high impedance fault event location in a distribution system is provided. The method includes determining a topology ranking for sensors in a distribution system. The topology refers to the arrangement of sensors with respect to one another in network. The topology ranking represents a number of steps from a power source to a sensor with respect to the direction of current flow The method further includes receiving an alarm at a central processor indicating a high impedance fault event, transmitting a request for data associated with the high impedance fault event to the plurality of sensors and a plurality of edge processing devices in the distribution system, receiving the requested data from the edge processing devices and determining a relative location of the high impedance fault event with respect to one of the plurality of sensors using the requested data and the topology ranking.

### STATEMENT REGARDING GOVERNMENT FUNDING

This invention was made with government support under CBMESSR, 8155.23.GV project, contract number W9132T-22-C-0026. The Federal Government has certain rights to this invention.

### TECHNICAL FIELD

The present disclosure relates to systems, methods and devices for locating and isolating high impedance faults in electric power distribution systems, in particular, in radial power systems.

### BACKGROUND

Catastrophic wildfires often lead to the loss of life and extensive property damage. Electric power distribution systems are also damaged by wildfires which result in power outages within the electrical power distribution system. Increasing prevalence of wildfires may be attributed to rising temperatures, population growth, and water shortages.

Traditional fault location techniques estimate the fault location based on the measured impedance magnitude, voltage drop from fault location to source, network model or application of traveling wave strategy in transmission lines. Advanced machine learning methods have been implemented for high impedance (“HiZ”) fault localization. One method uses wavelet transformation of voltage signals and support vector machine (SVM), and another method combines artificial neural networks with frequency spectral characteristics of post-fault measurements.

### BRIEF SUMMARY

In accordance with the present disclosure, fault location systems, devices and methods locate the positions of HiZ faults in electric power distribution systems based on characteristics of HiZ faults and topology information of the distribution systems. Locating HiZ faults quickly, minimizes the cost of HiZ fault damage, mitigates risks associated with HiZ faults, and aids in maintaining power coverage to other regions of the distribution system.

A method for locating a high impedance fault event location in a distribution system includes the steps of: determining a topology ranking for each of a plurality of sensors in a distribution system; receiving an alarm at a central processor indicating a high impedance fault event; transmitting a request for data associated with the high impedance fault event to the plurality of edge processing devices in the distribution system; receiving the requested data from the edge processing devices; and determining a relative location of the high impedance fault event with respect to one of the plurality of sensors using the requested data and the topology ranking.

A radial power system includes at least one power source, a plurality of sensors, a plurality of edge devices, and a central processor. Each of the plurality of sensors is positioned at a unique location within the radial power system and calculates harmonic energy values based on detected electrical signals. Each of the plurality of edge processing devices is connected to at least one sensor and configured to detect a high impedance fault event within the radial power system based on the harmonic energy values received from the sensors. The central processor is connected to the plurality of edge processing devices. The central processor is configured to determine a relative location of the high impedance fault event in the radial power system using a topology ranking for each of the plurality of sensors.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 illustrates a schematic system diagram for a distribution network;

FIG. 2A illustrates an operating environment for a distribution network;

FIG. 2B illustrates a process flow diagram for a distribution network;

FIG. 3 illustrates a method for determining a relative location of a high impedance fault in a distribution network;

FIGS. 4A to 4E illustrate variables used to determine the relative location of a high impedance fault in a distribution network;

FIG. 5A illustrates a topology of a distribution network having a plurality of nodes;

FIG. 5B illustrates a directed graph of the plurality of nodes shown in FIG. 5A after sorting;

FIG. 5C illustrates a chart of topology rankings for each sensor;

FIG. 6 illustrates a method of sorting a topology of a distribution network;

FIGS. 7A to 7E illustrate harmonic values over time for a plurality of sensors in a distribution network;

FIGS. 8A to 8E illustrate voltage over time for a plurality of sensors in a distribution network;

FIG. 9A illustrates a topology of a distribution network having a plurality of nodes;

FIG. 9B illustrates a schematic diagram of the plurality of nodes shown in FIG. 9A after sorting;

FIG. 9C illustrates a chart of topology rankings for each sensor;

FIGS. 10A to 10C illustrate harmonic values over time for a plurality of sensors in a distribution network; and

FIG. 11 illustrates a central processing unit for a distribution network.

### DETAILED DESCRIPTION

Approximately 30% of wildfire hazards in electric power distribution systems are linked to downed conductors, overhead lines contacting vegetation, and conductor slapping in medium-voltage overhead lines. These events may lead to high impedance faults in the distribution system. A high impedance fault (“HiZ”) occurs when an energized electrical conductor comes into contact with a highly resistive object, such as a tree, structure, or the ground, and a large impedance limits the flow of electrical current in the distribution system. HiZ faults are a major concern in medium-voltage overhead distribution systems with voltages below 70 kV. These faults are transient and, unlike typical ground faults, do not produce substantial currents that trip standard over-current protection devices in distribution systems.

Traditional fault location techniques may be significantly affected by factors such as fault type, unbalanced loads, and heterogeneity of overhead lines. In addition, these techniques do not consider the topology of the distribution systems. Topology varies from one distribution network to another, and topology varies within a distribution network when, for example, the direction of current flow changes due to adding or removing power sources at different locations in the network and/or opening and closing breakers. The change in topology can impact the accuracy of machine learning based fault location technology.

Mitigating risks associated with HiZ faults in distribution systems has been a long-standing issue for utility providers. The rapid growth of distributed energy resources (“DER”) in distribution systems has made the detection of HiZ faults more challenging because the DER may cause changes in system topology when the DER are connected or disconnected to the systems. Additionally, DERs can lead to back feeding the grid, essentially changing current flow in the grid without any change in breaker status. DERs are often integrated through inverters, which can produce harmonics leading to false alarms for HiZ fault detection. Thus, a reliable and accurate HiZ fault location system is needed to locate HiZ faults in power systems.

In accordance with the present disclosure, fault location systems, devices and methods locate the positions of HiZ faults in electric power distribution systems based on characteristics of HiZ faults and topology information of the distribution systems. Locating HiZ faults quickly, minimizes the cost of HiZ fault damage, mitigates risks associated with HiZ faults, and aids in maintaining power coverage to other regions of the distribution system.

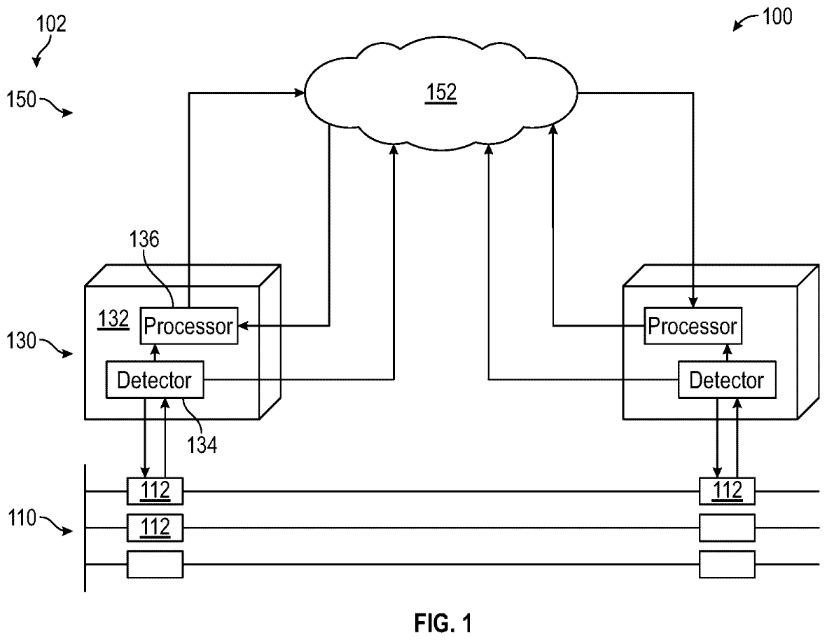

FIG. 1 illustrates a schematic system diagram for a distribution network 100 having a system architecture 102. System architecture 102 includes three layers, a first layer 110, a second layer 130 and a third layer 150. Each layer is in direct or indirect communication with the other layers providing an internet of things (IoT) framework with an edge-cloud/central processor system. Third layer 150 includes a cloud or central processor 152, second layer 130 includes a plurality of edge devices 132 and first layer 110 includes a plurality of sensors 112. As illustrated in FIG. 1, sensors 112 are in communication with edge devices 132. Sensors 112 are located throughout distribution network 100 at unique locations; sensors 112 may be located on a variety of components or nodes including power sources, loads, power lines, and breakers and may include smart devices. Edge devices 132 are in communication with sensors 112 and central processor 152. Edge devices 132 have computing power, perform calculations and collect and process data from sensors 112 and central processor 152. In various implementations, edge devices 132 include processors 136 and detectors 134 for processing, computing and calculating. Edge computing in the second layer 130 of system architecture 102 reduces the amount and type of data that needs to be sent to central processor 152 which reduces data transfer, increases processing speeds and reduces stress on central processor 152. Central processor 152 maintains and processes system wide knowledge from the plurality of edge devices 132 and sensors 112 to control distribution network 100.

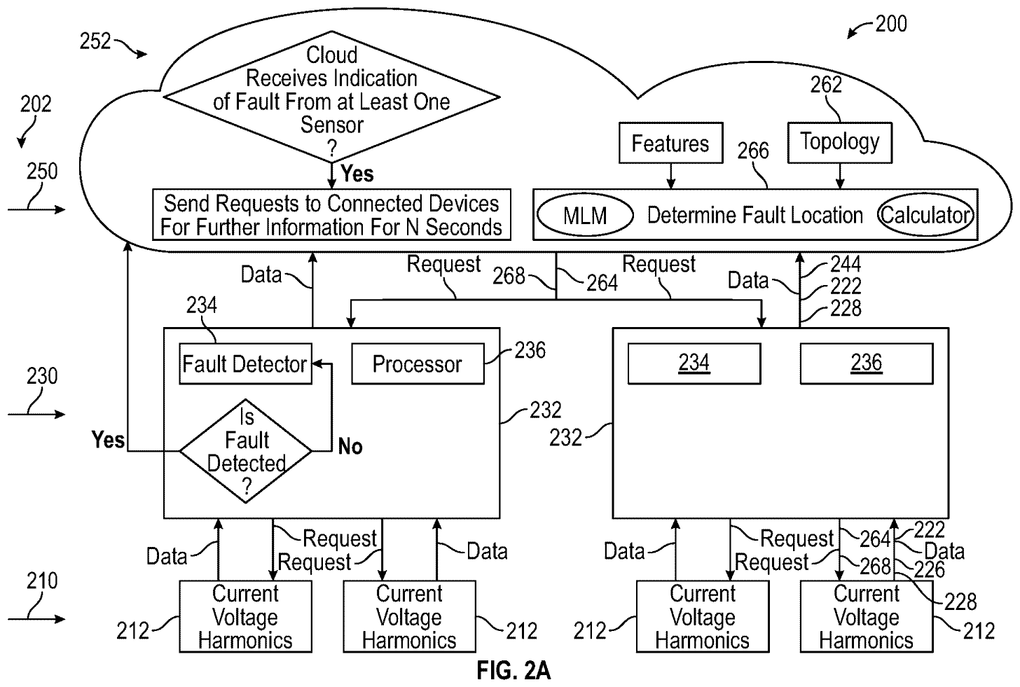

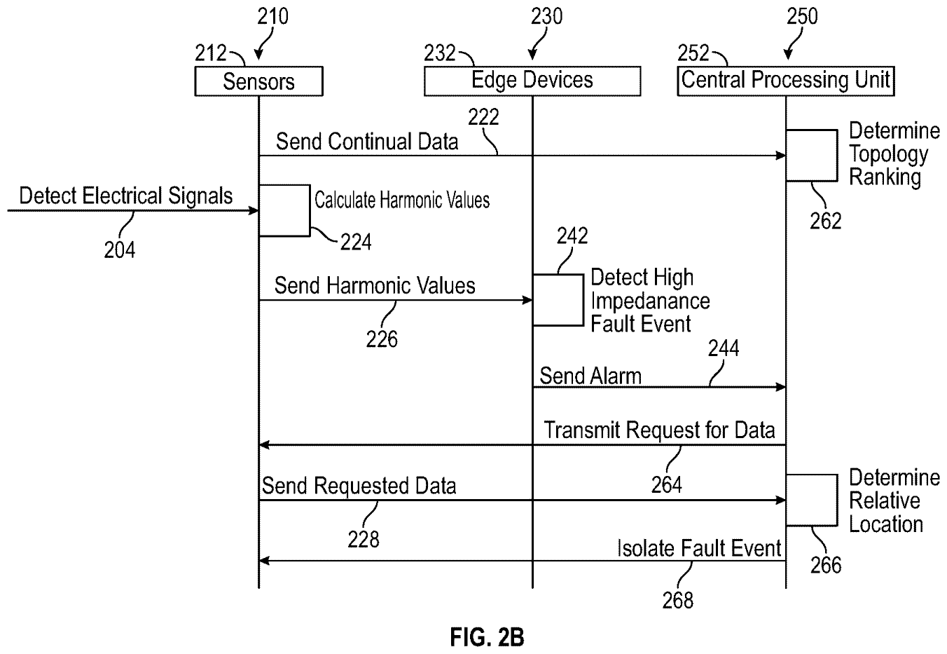

FIG. 2A illustrates an operating environment and FIG. 2B illustrates a process flow diagram for a distribution network 200. Distribution network 200 includes a system architecture 202 having three layers, a first layer 210, a second layer 230 and a third layer 250. System architecture 202 includes an edge-cloud framework. First layer 210 includes a plurality of sensors 212 on nodes at different locations throughout distribution network 200. Second layer 230 includes edge processing devices 232, each edge processing device 232 is in communication with at least one sensor in first layer 210. Third layer 250 includes cloud/central processor 252 for controlling distribution network 200. Cloud/central processor 252 directly communicates with edge processing devices 232 and indirectly communicates with sensors 212 via second layer 230.

First layer 210 transmits data to second and third layers 230, 250 and receives requests and commands from second and third layers 230, 250. In accordance with the present disclosure, sensors 212 transmit data: (a) to edge processing devices 232 for detecting a HiZ fault event; (b) to cloud/central processor 252 for determining topology rankings; and (c) to cloud/central processor 252 for locating a HiZ fault event. As an example, topology information can be learnt from data such as current direction and RMS magnitudes of currents and voltages from each sensor. The sensors talk to cloud/central processor 252 through SCADA (Supervisory Control and Data Acquisition) communication where such data is normally available.

Sensors 212 are located on various nodes and power lines throughout distribution network 200. In one implementation, distribution network 200 may be a residential electric power system in which nodes include power sources, loads (homes), and breakers. Sensors 212 detect transient electrical signals 204 such as current and voltage signals including current direction, current amplitude, current magnitude, and breaker status (e.g., open or closed) and process the electrical signals to obtain time series data. Sensors 212 transmit this data to edge processing devices 232 and cloud/central processor 252.

Sensors 212 transmit time series data or harmonic energy values derived therefrom to edge processing devices 232 continuously or at frequent intervals for detection of HiZ fault events. In some implementations, sensors 212 calculate harmonic energy values 224 from the time series data and send the harmonic energy values 226 to edge processing devices 232. In other implementations, sensors 212 transmit time series data and edge processing devices 232 process the time series data to obtain harmonic energy values. If, for example, the sensors 212 have enough computational resources, the calculation of harmonic energy values can be done in at the first level 210. Otherwise, the calculation of harmonic energy values can be done at the second level 230. In some cases, the sensors 212 may even have enough computational power to run a HiZ detection algorithm to detect a HiZ fault event. Otherwise, the harmonic energy values are used by edge processing devices 232 to detect a HiZ fault event which will be discussed in more detail below.

In addition, sensors 212 continually transmit data 222 to third layer 250 via second layer 230 so cloud/central processor 252 can determine topology rankings 262 for each sensor 212 in network 200. Sensors 212 continually transmit data, for example, current direction, current amplitude, and breaker status, to cloud/central processor 252 because a change in the direction of current flow in network 200 may change the topology rankings of some or all of sensors 212. This data may be sent repeatedly, every five seconds or so, for example. To reduce the amount of data sent to cloud/central processor 252, sensors 212 and/or edge processing devices 232 may transmit current direction, current amplitude, and breaker status data to cloud/central processor 252 for initial topology ranking determinations and transmit data thereafter when a change in the data (current direction, current amplitude, or breaker status) occurs. In this way, the amount of data sent to cloud/central processor 252 may be reduced resulting in less stress on network 200.

Sensors 212 also transmit data to second and third layers 230, 250 upon request. Cloud/central processor 252 transmits a request for data 264 from sensors 212 across distribution network 200 when a HiZ fault event has been detected by an edge device 232. Cloud/central processor 252 requests information regarding several variables including, for example, current timeseries data or voltage timeseries data. From the current timeseries data or voltage time series data, the cloud/central process can compute variables such as detection time, detection duration, and mean harmonic amplitude changes for high fidelity events (128 or 256 samples per power cycle or 16 ms or a fidelity of 125 microseconds). In other cases, variables such as detection time, detection duration, and mean harmonic amplitude changes can be requested by cloud/central processor 252 directly from the second layer 230. Sensors 212 receive the request and send the requested data 228 to cloud/central processor 252 for processing.

Second layer 230 receives data from first layer 210 and transmits data to and receives requests and commands from third layer 250. In accordance with the present disclosure, edge processing devices 232: (a) detect HiZ fault events based on data received from sensors 212; (b) send alarms to cloud/central processor 252 when HiZ fault events are detected; and (c) transmit and receive requests, commands and data between sensors 212 and cloud/central processor 252.

Edge processing devices 232 include a robust computing platform capable of implementing full or in part the HiZ detection algorithms, examples of which are disclosed in PCT Application Nos. PCT/EP2024/063777 and PCT/EP2024/063756 which are incorporated herein by reference. In some cases, the edge processing device 232 runs a part of the HiZ detection algorithm while the remaining portion is performed by cloud/central processor 252. Edge processing devices 232 input harmonic energy values received from sensors 212 into the HiZ detection algorithms to continuously monitor network 200 for HiZ fault events. In various implementations, edge processing devices 232 receive time series data from sensors 212 and process the time series data to obtain the harmonic energy values that are subsequently input into the algorithms. Harmonic energy values of the third or fifth harmonic value may be input into the algorithms. Individual low order harmonics, odd, even or interharmonics may be input into the algorithms.

A HiZ fault event is detected when changes in certain characteristics of harmonic values occur. When a HiZ fault event is detected in one of the edge processing devices 232, that particular edge processing device 232 sends an alarm 244 to cloud/central processor 252 alerting cloud/central processor 252 to the HiZ fault event. In response, cloud/central processor 252 transmits a request for additional data 264 to connected device in first and second layers 210, 230, i.e., edge processing devices 232 and sensors 212. In reply to the data request, sensors 212 send the requested data 228 to cloud/central processor 252 via edge processing devices 232.

As illustrated in FIG. 2A, edge processing devices 232 include a fault detector 234 and a processor 236. Fault detector 234 and processor 236 are shown as distinct boxes for illustrative purposes only. In various implementations, the functions may be carried out by the same, overlapping, or disjointed hardware as needed or desired.

Third layer 250 is in communication with first layer 210 and second layer 230. In accordance with the present disclosure, cloud/central processor 252: (a) determines a topology ranking for each sensor 212 in the network 200; (b) determines the location of a HiZ fault event using the topology ranking in combination with requested data from sensors 212 and edge processing devices 232; and (c) sends a command to isolate the HiZ fault event.

Cloud/central processor 252 transmits requests to all edge devices 232 for data when a HiZ fault event is detected by any edge device 232. In accordance with the present disclosure, cloud/central processor 252 determines a topology ranking for each sensor 212 in the network 200. When cloud/central processor 252 receives data from one of the edge devices 232 that a HiZ fault event has been detected, central processor 252 locates the position of the HiZ fault event using the topology ranking and data received from sensors 212. Cloud/central processor 252 isolates the HiZ fault event by sending a command 268 to open a corresponding breaker or set of breakers that are the closest to and located upstream of the HiZ fault event location to de-energize the HiZ fault thereby lowering the risk of fire at the location of the HiZ fault event and lowering damage and power failures throughout network 200.

The three layers 210, 230, 250 of system architecture 202 provide an accelerated response time from HiZ fault event detection by edge devices 232 to de-energization by cloud/central processor 252. By quickly locating the HiZ fault event using system-wide knowledge of the affected areas of network 200, the correct breaker or set of breakers can be opened to mitigate risks to the network 200.

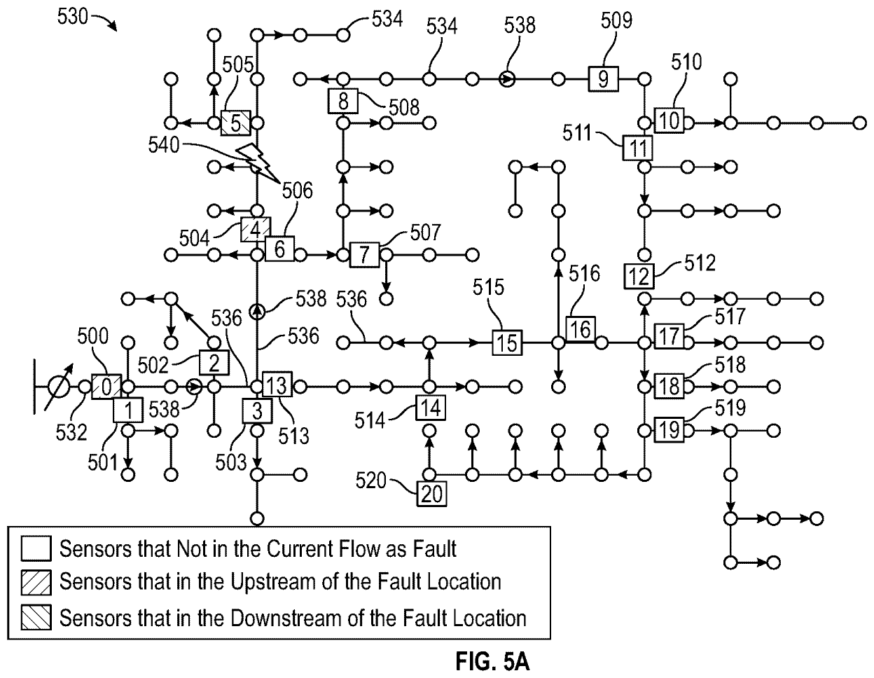

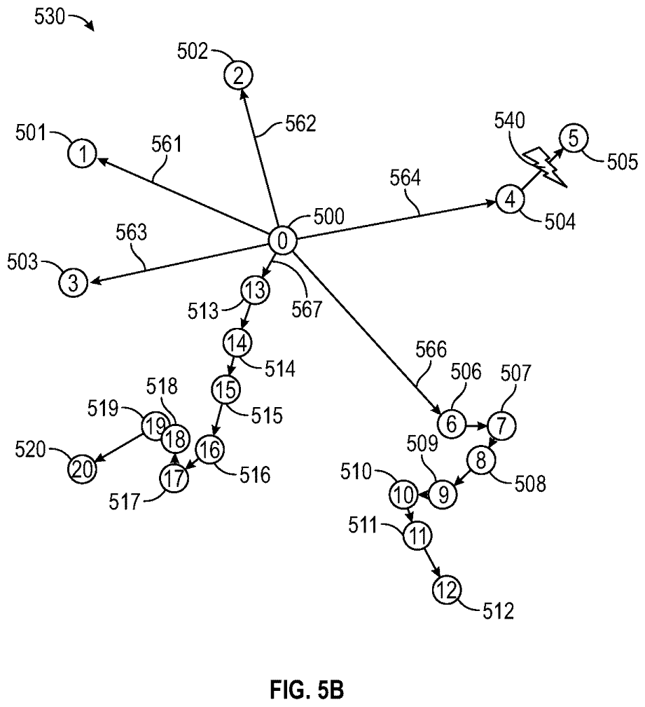

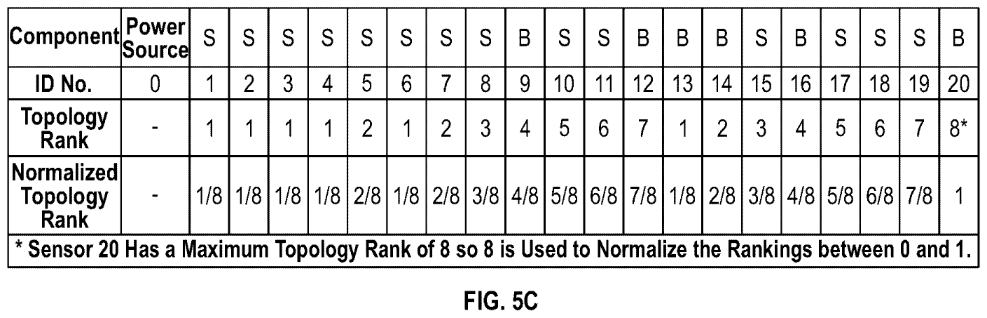

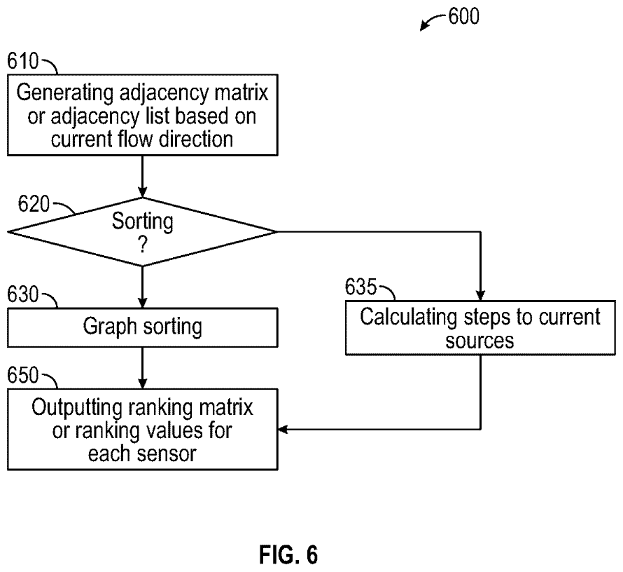

As explained above, sensors 212 continually send data to cloud/central processor 252 regarding current direction, current amplitude, and breaker status so a topology of the distribution network 200 can be considered when a location of a HiZ fault event needs to be ascertained. The topology refers to the arrangement of sensors 212 with respect to one another in network 200 and will be further explained below with reference to FIGS. 5A, 5B, 5C and 6. Cloud/central processor 252 determines an initial topology ranking for each sensor 212 based on a direction of current flow in network 200. The initial topology rankings are updated in real-time when the direction of current flow in network 200 changes. The direction of current flow may change as power sources are taken on or off the network and/or when breakers are opened or closed, for example. Thus, cloud/central processor 252 maintains an accurate mapping of the topology of the network 200 in real-time.

When cloud/central processor 252 receives an alarm indicating a HiZ fault event has been detected in an edge processing device 232, cloud/central processor 252 transmits a request for data 264 to all connected devices in first layer 210 and second layer 230, specifically sensors 212 and edge processing devices 232. Cloud/central processor 252 requests data for variables over an upcoming given period of time including, for example, detection time, detection duration, and mean harmonic amplitude changes, because these variables are associated with a location of a HiZ fault event. Sensors 212 close to a HiZ fault event location generally have greater amplitude changes in harmonic energy values, earlier detection (detection time) and longer detection duration, i.e., the changes in amplitude last longer. The given period of time may begin immediately or as quickly as possible and be a few seconds long, for example, 2 to 3 seconds of time. Providing a short time period reduces the amount of data transmission across network 200 and quickly enables cloud/central processor 252 to determine the location of the HiZ fault event and mitigate risks associated therewith.

In accordance with the present disclosure, a location metric f determines which sensor 212 is the closest upstream sensor to the HiZ fault location, thus providing the relative location of the HiZ fault event with respect to a location of a sensor 212 in network 200. Sensors 212 are encoded with physical location data so the corresponding physical location of the HiZ fault event can also be determined. Cloud/central processor 252 determines a final HiZ fault event location by determining a maximum value of location metric f using Equation (1) below (Calculator) or using a machine learning model (MLM) using a binary classification model or a multi-classification model including logistic regression, random forest, or decision tree.

$$f = HiZ detection status \times \sqrt{mean harmonics} \times \frac{1}{detection\_time} \times dectection duration \times topology {ranking}^{2} \qquad Eq ( 1 )$$

The variables of Eq (1) correlated to a HiZ fault location include a HiZ detection status, mean harmonic amplitude change (“mean harmonics”), detection time, detection duration and topology ranking. The HiZ detection status is a binary number between 0 and 1, i.e., 0 or 1. A value of 0 indicates no detection of a HiZ fault event in the corresponding edge processing device, whereas a value of 1 signifies a detected HiZ fault event in the edge processing device. Thus, if only one edge processing device detects a HiZ fault event, the sensors connected to that edge processing device will have location metric f values greater than 0, whereas the remaining sensors that are connected to other edge processing devices will have location metric values f equal to 0 because the HiZ detection status is 0 when no HiZ fault event was detected. Consequently, computing is done quickly for the remaining sensors.

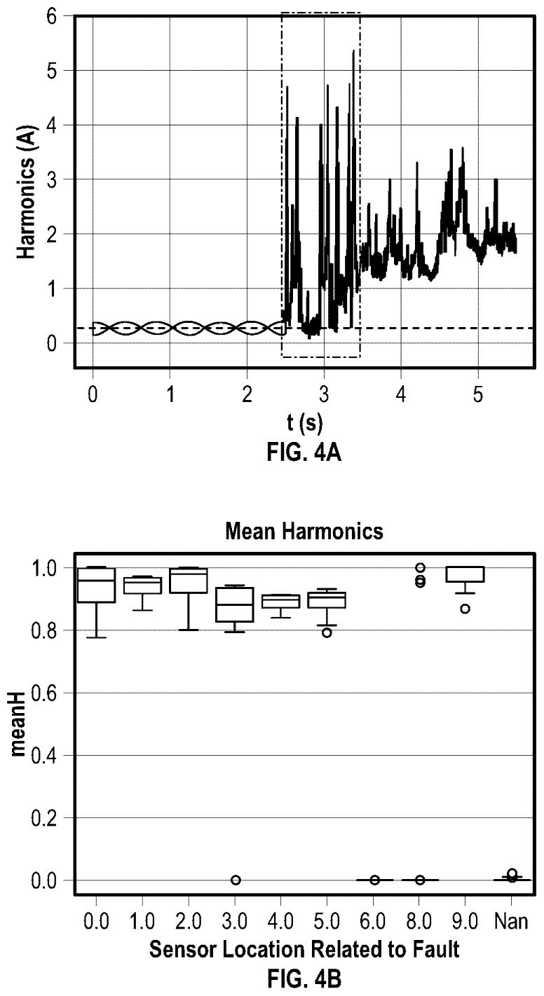

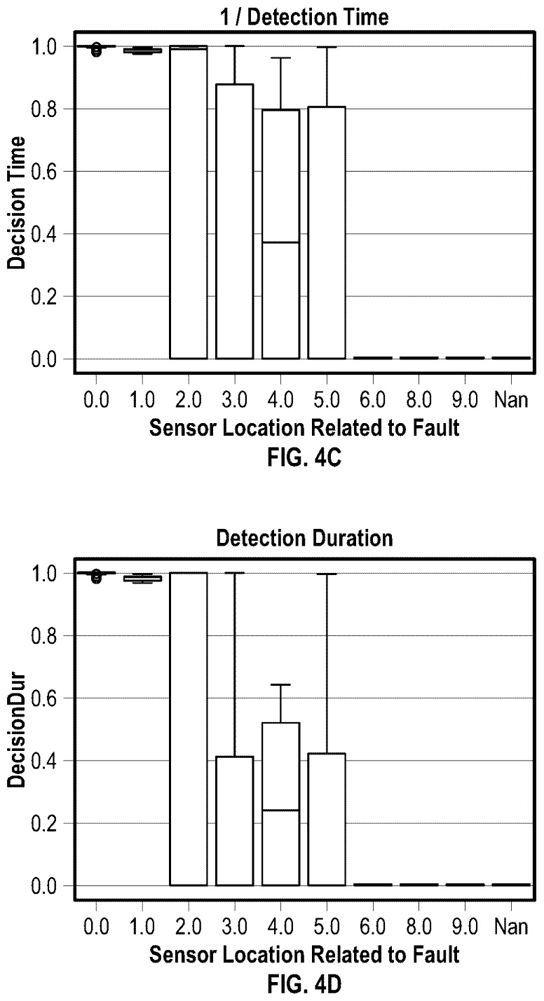

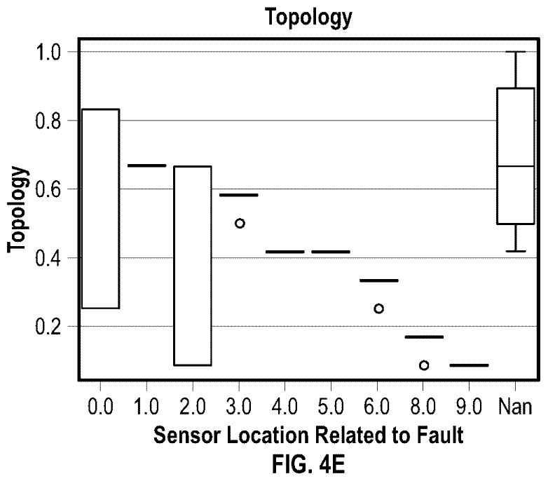

Mean harmonic amplitude change denotes the mean value of the change in amplitude of the harmonic energy values with respect to a baseline amplitude within a given period of time. For example, as shown in FIG. 4A, the change in the amplitude of the baseline harmonics occurs between 2 and 2.5 seconds. The baseline amplitude is less than 0.5 A prior to the change and increases sharply to a high of nearly 5.5 A. For use in Eq (1), the mean harmonic amplitude change values are normalized between 0 and 1. To normalize the values, the mean harmonic amplitude change for each sensor is determined and the maximum value is used as denominator. Each mean harmonic value is divided by the denominator, resulting in mean Harmonic values between 0 and 1. FIG. 4B illustrates normalized mean harmonic values between 0 and 1 for a plurality of sensors relative to the steps from the sensors to the fault location. For example, if a sensor is not in the same branch as the fault, the number of steps to the fault is represented on the x-axis as Nan.

Detection time is the time a HiZ fault event is first detected by the sensor relative to an initial start time. The initial start time will be the request time from the central processor minus a buffer time. Since the value of Eq (1) is proportional to 1/Detection time, here we use detection time to represent the value of 1/Detection time. The detection time for the sensors that don't detect HiZ fault event is 0. Detection time is also normalized for use in Eq (1), each detection time is divided by the maximum detection time. Maximum detection time is a time with respect to an initial start time. For example, the request time from the central processor is 4:00 PM. As there is a buffer to record a certain duration of data, e.g., 5 sec of data pre-request, the start time will be 3:55 PM. If the fault is detected at 4:02 PM by the sensor, the detection time of the sensor will be 7 sec. The maximum detection time will be the maximum value over all the sensors that detect the HiZ fault.

Detection duration refers to the duration of time for which a HiZ fault event is consistently detected within a defined window of time. Detection duration values are normalized for use in Eq (1) by dividing each detection duration value by the maximum detection duration value resulting in normalized values between 0 and 1. FIG. 4D illustrates normalized decision duration values between 0 and 1 for a plurality of sensors relative to the steps from the sensors to the fault location.

Topology ranking represents a number of steps from a power source to a sensor with respect to the direction of current flow. Topology ranking values are normalized for use in Eq (1). The number of steps from a power source to each sensor is determined. The maximum number of steps from a power source to the furthest sensor is identified. Each number of steps is divided by the maximum number of steps resulting in normalized values between 0 and 1. FIG. 4E illustrates normalized topology ranking values between 0 and 1 for a plurality of sensors. Topology ranking will be further explained below with respect to FIGS. 5A, 5B, 5C and 6.

Once cloud/central processor 252 has the requested data 228 from first and second layers 210, 230, cloud/central processor 252 processes the data to determine a relative location of the HiZ fault event 266 with respect to one of the sensors 212 in network 200 using Eq (1) or a machine learning model. Upon locating the HiZ fault event, cloud/central processor 252 can isolate the HiZ fault event by opening the nearest upstream breaker. Opening the nearest upstream breaker prevents current from flowing into the HiZ fault event and mitigates risks associated therewith.

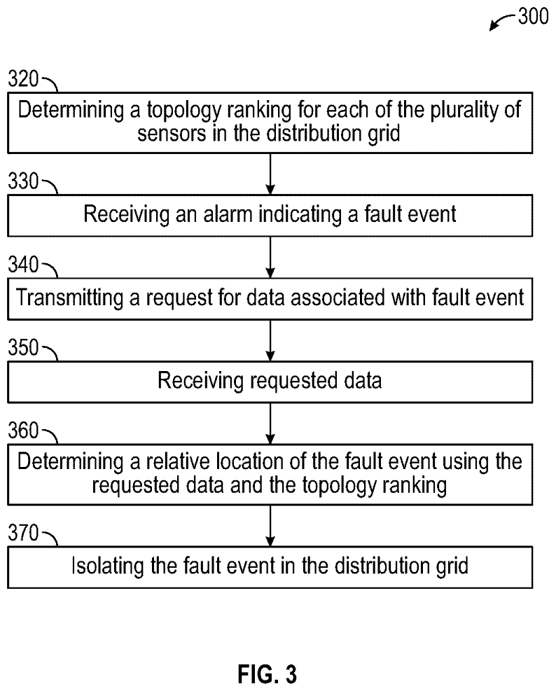

FIG. 3 illustrates a method 300 for determining a relative location of a high impedance fault in a distribution grid having a central processing unit, a plurality of edge devices and a plurality of sensors as illustrated in FIG. 1. A central processing unit, for example, a central processor, a server or a cloud determines (320) a topology ranking for each of the plurality of sensors in the distribution grid using data received from a plurality of sensors in the grid. The topology ranking represents the number of steps from a power source to a sensor with respect to a direction of current flow. The topology rankings may be updated when the power source and/or direction of current flow changes in the grid. Central processing unit receives (330) an alarm indicating that a HiZ fault event has been detected. In response to the alarm, central processing unit transmits (340) a request for data associated with the HiZ fault event to the connected devices in the grid, e.g., the edge devices and sensors, for more detailed information for an upcoming given period of time, e.g., for the next two or three seconds. The requested data may include a HiZ detection status, mean harmonic amplitude changes, detection times, and detection durations. Once the central processing unit receives (350) the requested data, the central processor determines (360) a relative location of the HiZ fault event using the topology ranking and the requested data to identify the nearest upstream sensor, that is, the sensor with the highest location metric value f. Central processing unit then isolates (370) the HiZ fault event in the distribution grid by sending a command to open the nearest upstream breaker in order to prevent current from flowing to the HiZ fault event location.

FIGS. 4A to 4E illustrate variables used to determine the relative location of a high impedance fault in a distribution network. FIG. 4A illustrates harmonic energy values over time for a sensor in a distribution network. FIG. 4B illustrates normalized values for mean harmonic amplitude changes for a plurality of sensors with respect to a fault location. FIG. 4C illustrates normalized values for detection time for a plurality of sensors with respect to a fault location. FIG. 4D illustrates normalized values for detection duration for a plurality of sensors with respect to a fault location. FIG. 4E illustrates normalized values for topology ranking for a plurality of sensors with respect to a fault location.

FIG. 5A illustrates a topology of a distribution network having a plurality of nodes, FIG. 5B illustrates a schematic diagram of a plurality of sensors shown in FIG. 5A after sorting and FIG. 5C is a chart illustrating topology rankings and normalized topology rankings for each sensor.

Topology refers to a network of components in an electrical power distribution system and the power lines that connect the components with each other. A system with radial topology includes components connected in series with each other starting at a power source. Power lines, including overhead power lines and underground cables, emanating from the power source connect various components throughout the distribution system. The topology refers to a plot of the pathways from the source to the different components. The components in an electrical power distribution system may include sensors, breakers, transformers, power lines, loads (e.g., homes, businesses, consumer end users), power sources including substations and transformers, and distributed energy resources (“DER”) (e.g., solar panels). A system with radial topology does not include closed loops and is often described as a tree with branches.

Electrical power distribution systems exhibit diverse topologies, which can significantly affect fault detection. In accordance with the present disclosure, topology information including a relative location of a sensor and the current flow direction is used to locate a HiZ fault event in the distribution system.

Topology information for each distributed system is based on current flow direction. The topology information of each sensor is encoded into a ranking variable or ranking matrix using adjacency sets. The adjacency sets contain pairs of nodes that have direct current flow from one to another. A directed graph is used to order the sensors in the electrical power distribution system. Each sensor represents a vertex. When current flows directly from sensor A to sensor B, an edge is established from A to B, A→B, such that vertex A comes before B in the ordering. The adjacency sets can be dynamically generated from current flow direction information from a SCADA system or other current direction measurement devices.

Sensors can be sorted using traditional graph sorting techniques or calculating the distance to current sources. To calculate the distance to current sources, the number of steps from a sensor upstream to a power source are counted with respect to the direction of current flow. Each power source has its own distance vector. The distance to current sources for each sensor is output as a ranking matrix or ranking values.

If there is no closed loop inside the power distribution system, the present disclosure is effective for use in systems with multiple power sources. The adjacency list of connected sensors can be updated quickly when a switching operation occurs, and the topology feature variable can be recalculated with the updated adjacency set.

As illustrated in FIG. 5A, a distribution network, for example, a radial power system 530, includes a power source 532, a plurality of nodes 534 and a plurality of sensors 500 to 520 at unique locations throughout radial power system 530. Radial power system 530 may be, for example, a residential power system in which nodes 534 include loads, e.g., homes, breakers, power sources, and distributed energy resources which are connected to one another by power lines 536, e.g., overhead power lines and underground cables. Sensors 500 to 520 may be located on various components throughout radial power system 530 including power source 532, nodes 534 and power lines 536. A direction of current flow through radial power system 530 starts at power source 532 and is identified by arrows 538 on power lines 536 carrying current to nodes 534 throughout radial power system 530. A HiZ fault event 540 is located downstream of sensor 504.

FIG. 5B illustrates a directed graph of sensors 500 to 520 after sorting by calculating the number of steps from each sensor upstream to a power source with respect to a direction of current flow. In FIG. 5B, sensor 500 corresponds to power source 532 so the number of steps (i.e., distance) upstream to sensor 500 from each sensor 501 to 520 is determined. The number of steps is the topology rank for each sensor shown in FIG. 5C.

As explained above, the direction of current flow is used to linearly order sensors 501 to 520 into adjacency sets. The adjacency sets are shown schematically in FIG. 5B. A plurality of branches 561, 562, 563, 564, 566, 567 radiate out from sensor 500 (power source 532). Branches 561, 562, 563 each include one sensor 500, 502, 503, respectively, whereas branches 564, 566, 567 each include a plurality of sensors. As illustrated in FIGS. 5A and 5B, the power source 532, sensor 500, and sensors 501 to 520 are arranged such that current flows from power source 532/sensor 500 directly to sensor 501, from power source 532/sensor 500 directly to sensor 502 and from power source 532/sensor 500 directly to sensor 503 without passing any intervening sensors. Thus, each of branches 561, 562, 563 includes one sensor. In contrast, in branch 564 current flows from power source 532/sensor 500 to sensor 504 (500→504) and further downstream to sensor 505 (504→505) as the direction of current flow indicates in FIG. 5A. Similar to branch 564, branches 566 and 567 include a plurality of sensors 506 to 512 and 513 to 520, respectively. Prior to reaching sensor 512, current passes through sensors 506 to 511 in branch 566 and prior to reaching sensor 520, current passes through sensors 513 to 519 in branch 567.

FIG. 5C illustrates a chart indicating the topology ranking and normalized topology ranking for each sensor 501 to 520. The topology ranking is equal to the distance or number of steps upstream from each sensor 501 to 520 to sensor 500 (power source 532). Thus, the minimum topology ranking is 1 because each sensor 501 to 520 needs at least one step to reach power source 532/sensor 500. To normalize the topology ranking values, each topology ranking is divided by the largest number of steps, i.e., the maximum topology ranking. In this example, the largest number of steps is 8 because sensor 520 is 8 steps away from sensor 500. Thus, each topology ranking is divided by 8 to obtain normalized values between 0 and 1.

FIG. 6 illustrates a method 600 of sorting sensors with respect to a topology of the distribution network. An adjacency matrix or an adjacency list is generated (610) to identify sensors having connected edges with respect to the direction of current flow. Sorting techniques are then applied (620). The sensors can be sorted (630) via graph sorting techniques or by calculating (635) the steps (i.e., distance) from the sensors to the current sources. After sorting (630), a ranking matrix or ranking values including the topology ranking for each sensor is output (650).

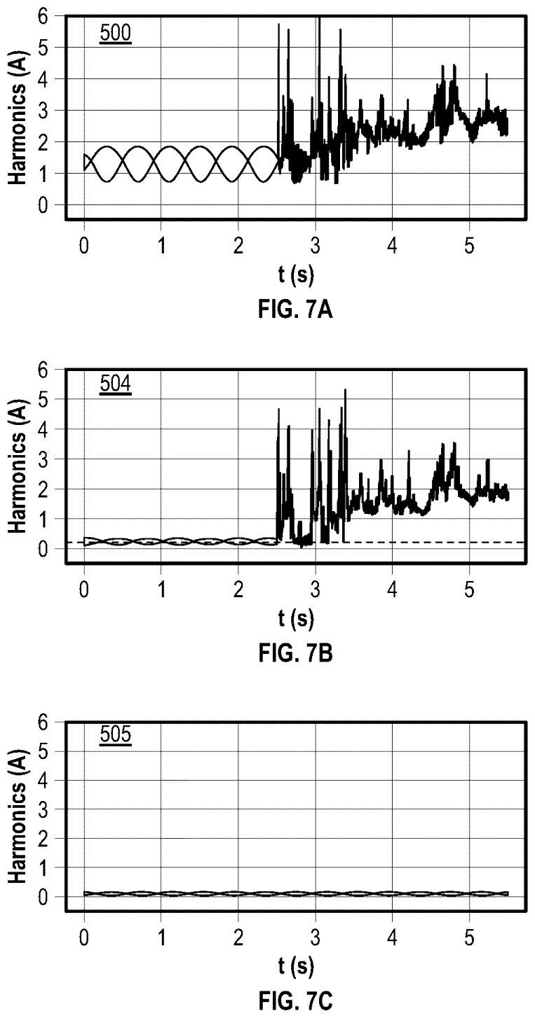

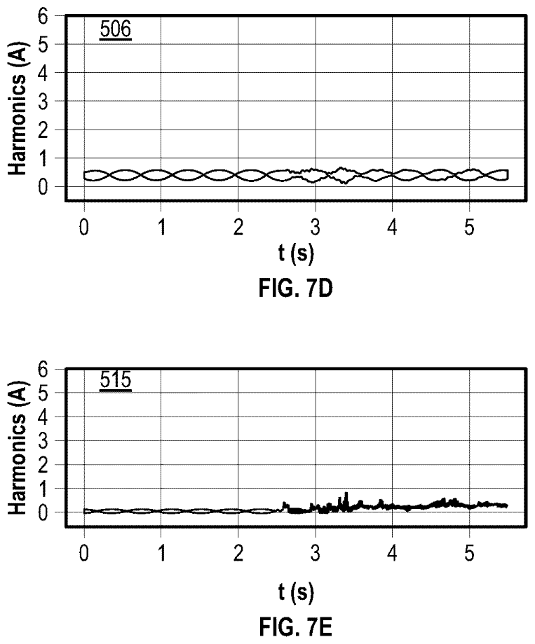

FIGS. 7A to 7E illustrate harmonic values over time for a plurality of sensors 500, 504, 505, 506, 515, respectively, in radial power system 530 illustrated in FIGS. 5A and 5B. Under normal operating conditions, harmonic energy values follow a sine wave pattern and establish a baseline amplitude. As explained above, a change in amplitude from the baseline amplitude is indicative of a HiZ fault event. With reference to FIGS. 5A to 5C, 7A and 7B, HiZ fault event 540 is located downstream from sensors 500 and 504 and upstream from sensor 505. The change in baseline amplitude for sensor 504 is greater than the change in baseline amplitude for sensor 500 indicating that sensor 504 is closer to the HiZ fault location. With respect to sensor 504, a significant change in baseline amplitude occurs at around 2.5 seconds. The baseline amplitude at sensor 504 is less than 0.5 A from 0 to 2.5 seconds and increases to about 4.5 A from 2.5 to 3.5 seconds for an approximate change in amplitude of 4 A, whereas in FIG. 7A, the baseline amplitude at sensor 500 is slightly greater than 1.0 A from 0 to 2.5 seconds and increases to about 4.5 A for an approximate change of 3.5 A. As illustrated in FIGS. 7A and 7B and in accordance with the present disclosure, larger changes in baseline amplitude indicate that sensor 504 is closer to the HiZ fault event 540 than sensor 500. As illustrated in FIGS. 7C to 7E, the baseline amplitudes of sensors 505, 506 and 515 remain relatively unchanged despite the HiZ fault event 540 because sensor 505 is downstream from the HiZ fault event 540 (FIGS. 5A and 5B) and sensors 506, 515 are in different branches 566, 567, respectively, than HiZ fault event 540 (FIG. 5B) and thus are not in the direction of current flow. Thus, FIGS. 7A to 7E show that significant changes in the baseline amplitude occur in in sensors upstream from a HiZ fault event and that baseline amplitudes remain unchanged in sensors downstream from the HiZ fault event and in sensors in other branches of current flow.

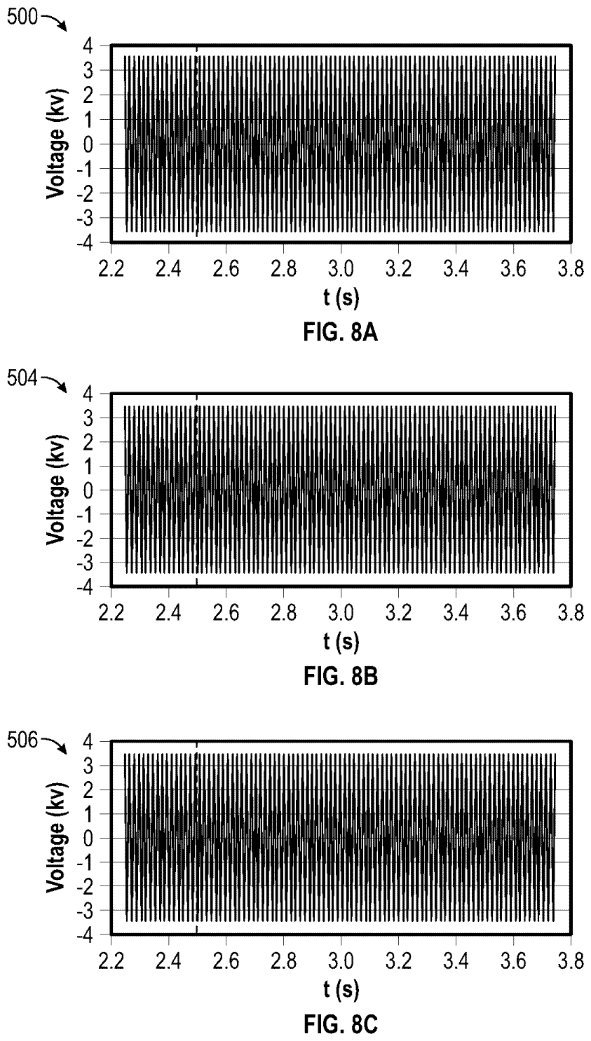

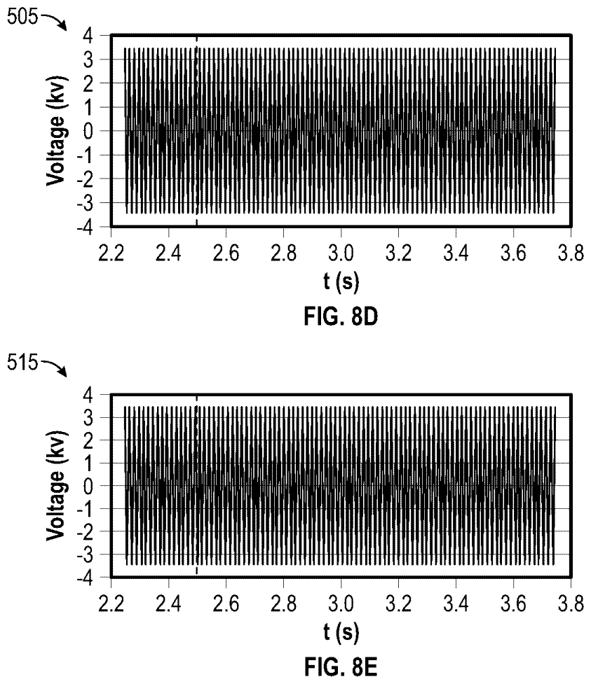

FIGS. 8A to 8E illustrate voltage over time for a plurality of sensors 500, 504, 506, 505, 515, respectively, in radial power system 530 illustrated in FIGS. 5A and 5B. As shown, there is no change in voltage detected in any of sensors 500, 504, 506, 505, 515, despite a HiZ fault event 540 occurring at 2.5 seconds. No change is detected in sensors 500, 504 downstream from HiZ fault event 540, no change is detected in sensor 505 upstream from HiZ fault event 540, and no change is detected in sensors 506, 515 located in different branches of current flow. Thus, changes in voltage cannot be relied on to locate HiZ fault events in distribution systems.

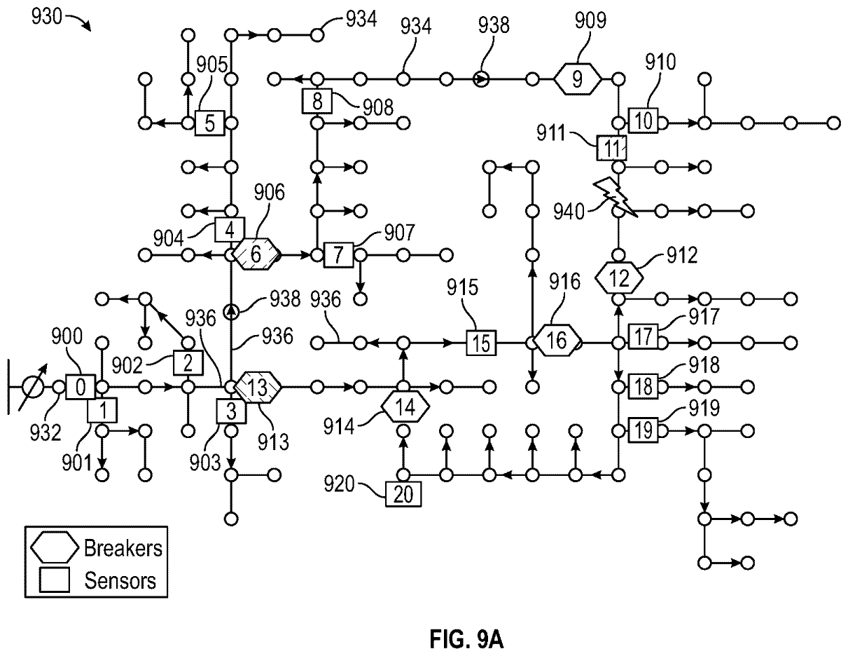

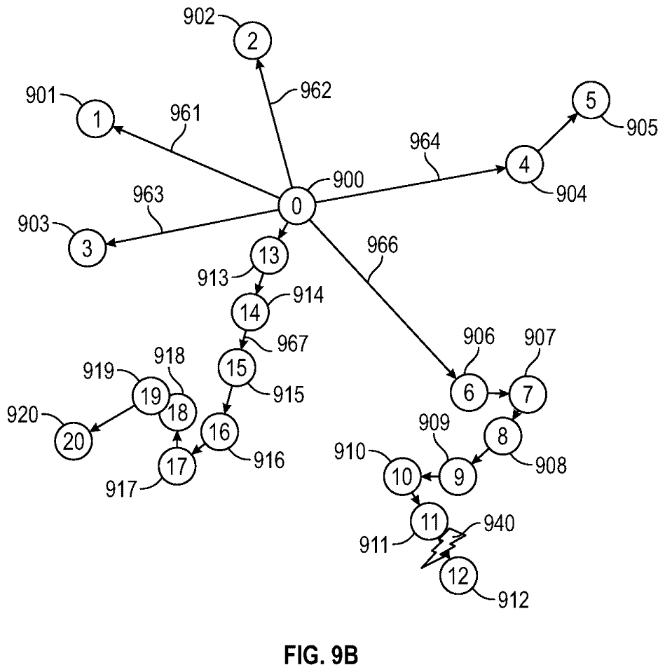

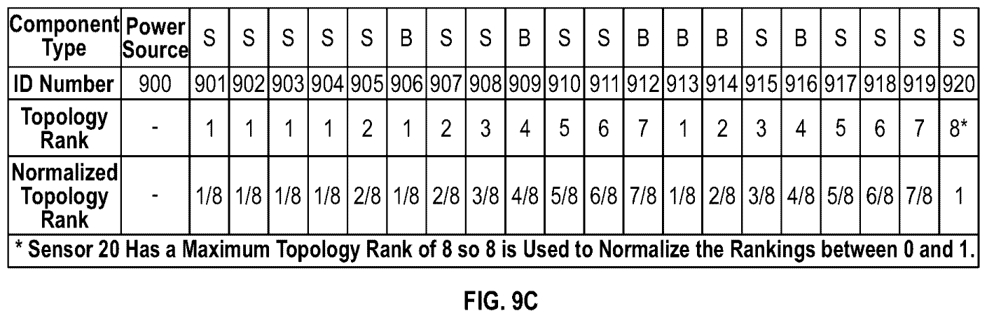

FIG. 9A illustrates a topology of a distribution network having a plurality of nodes, FIG. 9B illustrates a schematic diagram of a plurality of sensors shown in FIG. 9A after sorting and FIG. 9C is a chart illustrating topology rankings and normalized topology rankings for each sensor.

As illustrated in FIG. 9A, a distribution network, for example, a radial power system 930, includes a power source 932, a plurality of nodes 934 and a plurality of sensors 900 to 920 at unique locations. Sensors are located on various components throughout radial power system 930 including power source 932, nodes 934, breakers 906, 909, 912, 913, 914, 916, and power lines 936. The breakers also include sensing components that record currents and/or voltages. A direction of current flow through radial power system 930 starts at power source 932 and is identified by arrows 938 on power lines 936 carrying current to nodes 934. A HiZ fault event 940 is located downstream of sensor 911 and upstream of breaker 912.

FIG. 9B illustrates a schematic diagram of sensors 900 to 920 after sorting by calculating the number of steps from each sensor upstream to a power source with respect to a direction of current flow. Sensor 900 corresponds to power source 932 so the number of steps (i.e., distance) upstream to sensor 900 from each sensor 901 to 920 is determined. The number of steps is the topology ranking as shown in FIG. 9C.

As explained above, the direction of current flow is used to linearly order sensors 901 to 920 into adjacency sets shown schematically in FIG. 9B. Branches 961, 962, 963, 964, 966, 967 radiate out power source 932 (sensor 900) representing six different directions of current flow. Within each branch, current must flow through each sensor to reach the next sensor downstream. Branches 961, 962, 963 each include one sensor 901, 902, 903, respectively, so current flows from power source 932 directly to the respective sensor. Since each sensor 901, 902, 903 is only one step away from power source 932/sensor 900, sensors 901, 902, 903 each have a topology ranking of 1. Branches 964, 966, 967 each include a plurality of sensors so current flows from power source 932 through each consecutive sensor to reach the furthest downstream sensor. In branch 964, current flows from power source 932 to sensor 904 (900→904) and further downstream to sensor 905 (904→905). In branch 966, current flows from power source 932, through sensors 906 to 911 to reach downstream sensor 912. Similarly, in branch 967, current flows from power source 932, through sensors 913 to 919 to reach downstream sensor 920.

FIG. 9C illustrates a chart indicating the topology ranking and normalized topology ranking for each sensor 901 to 920. The topology ranking is equal to the distance or number of steps upstream from each sensor 901 to 920 to sensor 900 (power source 932). Thus, the minimum topology ranking is 1 because each sensor 901 to 920 needs at least one step to reach power source 932/sensor 900. To normalize the topology ranking values, each topology ranking is divided by the largest number of steps, i.e., the maximum topology ranking. In this example, the largest number of steps is 8 because sensor 920 is 8 steps away from sensor 900. Thus, each topology ranking is divided by 8 to obtain normalized values between 0 and 1.

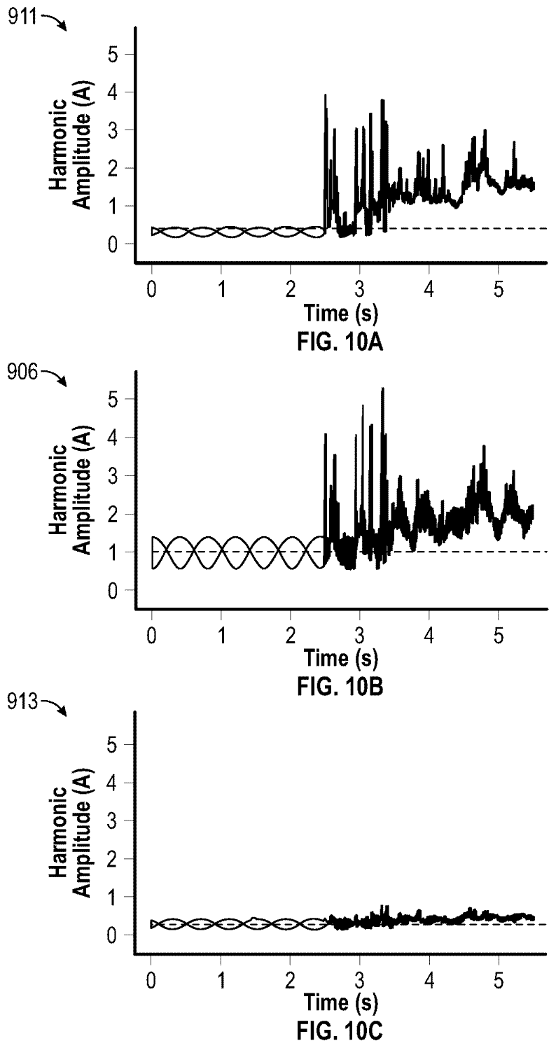

FIGS. 10A to 10C illustrate harmonic values over time for a plurality of sensors in 911, 906, 913, respectively, in radial power system 930 of FIGS. 9A and 9B. With reference to FIGS. 9A, 9B, 9C and 10A to 10C, sensors 906 and 911 and HiZ fault are located in branch 965. HiZ fault is downstream from both sensors 906 and 911. Sensor 913 is located in a different branch 967 and thus is not located upstream nor downstream from HiZ fault event 940.

As explained above, a change in harmonic amplitude from the baseline harmonic amplitude is indicative of a HiZ fault event. As illustrated in FIG. 10A, a significant change in baseline harmonic amplitude occurs at around 2.5 seconds for sensor 911, the sensor directly upstream from HiZ fault event 940. The baseline amplitude at sensor 911 is about 0.33 A from 0 to 2.5 seconds and increases to about 3.5 A from 2.5 to 3.5 seconds for an approximate change in amplitude of 3.17 A, whereas in FIG. 10B, the baseline amplitude at sensor 906 is about 1.0 A from 0 to 2.5 seconds and increases to about 4 A for an approximate change of 3 A. In accordance with the present disclosure, the larger change in baseline amplitude shown in FIG. 10A indicates that sensor 911 is closer to a location of HiZ fault event 940. In addition, as expected, the baseline amplitude of sensor 913 does not include any significant changes in baseline harmonic amplitude indicative of HiZ fault event 940 because sensor 913 is in a different branch than HiZ fault event 940. Thus, FIGS. 10A to 10C show that significant changes in the baseline amplitude occur in sensors upstream from a HiZ fault event and that baseline amplitudes remain unchanged in sensors in other branches of current flow.

To isolate HiZ fault event 940 in radial power system 930, the nearest upstream breaker 909 would be opened to prevent current from flowing to the HiZ fault location.

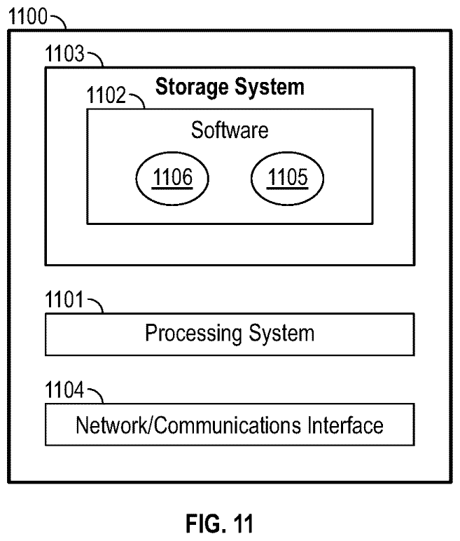

FIG. 11 illustrates components of a computing system that may be used in certain embodiments described herein. Referring to FIG. 11, system 1100 may be implemented within a single computing device or distributed across multiple computing devices or sub-systems that cooperate in executing program instructions. In some cases, system 1100 can be a firewall hardware device, router, or other computing system on a network. In general, system 1100 can include one or more blade server devices, standalone server devices, personal computers, routers, hubs, switches, bridges, firewall devices, intrusion detection devices, mainframe computers, network-attached storage devices, and other types of computing devices.

The system 1100 can include a processing system 1101, which may include one or more processors and/or other circuitry that retrieves and executes software 1102 from storage system 1103. Processing system 1101 may be implemented within a single processing device but may also be distributed across multiple processing devices or sub-systems that cooperate in executing program instructions.

Storage system(s) 1103 can include any computer readable storage media readable by processing system 1101 and capable of storing software 1102. Storage system 1103 may be implemented as a single storage device but may also be implemented across multiple storage devices or sub-systems co-located or distributed relative to each other. Storage system 1103 may include additional elements, such as a controller, capable of communicating with processing system 1101. Storage system 1103 may also include storage devices and/or sub-systems on which data is stored. System 1100 may access one or more storage resources in order to access information to carry out any of the processes indicated by software 1102.

Software 1102, including routines for performing processes, may be implemented in program instructions and among other functions may, when executed by system 1100 in general or processing system 1101 in particular, direct the system 1100 or processing system 1101 to operate as described herein. For example, software 1102 can include, but is not limited to, instructions for methods 300 and 600. These methods are depicted by applications 1105, 1106 in FIG. 11.

In embodiments where the system 1100 includes multiple computing devices, the server can include one or more communications networks that facilitate communication among the computing devices. For example, the one or more communications networks can include a local or wide area network that facilitates communication among the computing devices. One or more direct communication links can be included between the computing devices. In addition, in some cases, the computing devices can be installed at geographically distributed locations. In other cases, the multiple computing devices can be installed at a single geographic location, such as a server farm or an office.

A communication interface 1104 may be included, providing communication connections and devices that allow for communication between system 1100 and other computing systems (not shown) over a communication network or collection of networks (not shown) or the air.

In some embodiments, system 1100 may host one or more virtual machines.

Alternatively, or in addition, the functionality, methods, and processes described herein can be implemented, at least in part, by one or more hardware modules (or logic components). For example, the hardware modules can include, but are not limited to, application-specific integrated circuit (ASIC) chips, field programmable gate arrays (FPGAs), system-on-a-chip (SoC) systems, complex programmable logic devices (CPLDs) and other programmable logic devices now known or later developed. When the hardware modules are activated, the hardware modules perform the functionality, methods and processes included within the hardware modules.

It should be understood that as used herein, in no case do the terms “storage media,” “computer-readable storage media” or “computer-readable storage medium” consist of transitory carrier waves or propagating signals. Instead, “storage” media refers to non-transitory media.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts that would be recognized by one skilled in the art are intended to be within the scope of the claims.

What is claimed is:

1. A method for locating a high impedance fault event location in a distribution system comprising the steps of:
determining a topology ranking for each of a plurality of sensors in a distribution system;
receiving an alarm at a central processor indicating a high impedance fault event;
transmitting a request for data associated with the high impedance fault event to the plurality of sensors and a plurality of edge processing devices in the distribution system;
receiving the requested data from the edge processing devices; and
determining a relative location of the high impedance fault event with respect to one of the plurality of sensors using the requested data and the topology ranking.

2. The method of claim 1, wherein the relative location of the high impedance fault event is determined with respect to a sensor upstream from the high impedance fault event with respect to a direction of current flow in the distribution system.

3. The method of claim 1, further comprising:
transmitting a command to open a breaker in the distribution system to isolate the high impedance fault event.

4. The method of claim 3, wherein the breaker is upstream from the high impedance fault event with respect to a direction of current flow in the distribution system.

5. The method of claim 1, further comprising computing a detection time, a detection duration, a mean harmonic amplitude change, and a high impedance detection status for a period of time from the requested data, wherein the requested data includes current timeseries data or voltage timeseries data collected by the plurality of sensors, wherein detection time, detection duration, a mean harmonic amplitude change are each normalized for a maximum value recorded by the plurality of sensors.

6. The method of claim 1, wherein Equation (1) is used to determine the relative location of the high impedance fault event, wherein f is a location metric value for each sensor:
$$f = HiZ detection status \times \sqrt{mean harmonics} \times \frac{1}{detection\_time} \times dectection duration \times topology {ranking}^{2} . \qquad Eq ( 1 )$$

7. The method of claim 6, wherein the location metric value f is calculated for each sensor and a highest location metric value f indicates the sensor that is closest to and upstream from the high impedance fault event.

8. The method of claim 6, wherein the high impedance fault event is detected based on changes in amplitudes of harmonic energy values and wherein mean harmonics is a mean value of relative changes in amplitudes of harmonic energy values during the high impedance fault event.

9. The method of claim 6, wherein the topology ranking indicates a relative distance of each sensor from a current source with respect to a direction of current flow in the distribution system.

10. The method of claim 1, wherein determining a topology ranking for each of the plurality of sensors in the distribution system comprises:
generating an adjacent matrix or an adjacent list for the plurality of sensors based on a direction of current flow in the distribution system;
sorting the plurality of sensors in the distribution system; and
outputting the topology ranking for each sensor in the distribution system.

11. The method of claim 10, further comprising:
monitoring the direction of current flow for changes in real-time; and
generating a further adjacent matrix or a further adjacent list, respectively, for the plurality of sensors when the direction of current flow changes.

12. The method of claim 11, wherein the topology ranking changes if the direction of current flow changes.

13. The method of claim 11, wherein sorting the plurality of sensors includes:
using a graph sorting method to sort the plurality of sensors in the distribution system with respect to the direction of current flow; or
calculating a relative distance to a current source for each sensor in the distribution system with respect to the direction of current flow.

14. The method of claim 1, wherein the sensors calculate harmonic energy values based on detected electrical signals and send the harmonic energy values to one of the edge processing devices.

15. The method of claim 5, wherein a machine learning model uses the topology ranking, detection time, detection duration, mean harmonic amplitude change, and high impedance detection status as features to determine the relative location of the high impedance fault event.

16. A radial power system comprising:
at least one power source;
a plurality of sensors, each sensor positioned at a unique location within the radial power system, each sensor calculating harmonic energy values based on detected electrical signals;
a plurality of edge processing devices, each edge processing device connected to at least one sensor, each edge processing device configured to detect a high impedance fault event within the radial power system based on the harmonic energy values received from the sensors; and
a central processor, the plurality of edge processing devices connected to the central processor, the central processor configured to determine a relative location of the high impedance fault event in the radial power system using a topology ranking for each of the plurality of sensors.

17. The radial power system of claim 16, wherein the central processor uses mean harmonics, detection time, detection duration and a detection status to determine the relative location of the high impedance fault event.

18. The radial power system of claim 17, wherein the central processor uses Equation (1) to determine the relative location of the high impedance fault event, wherein f is a location metric value for each sensor:
$$f = HiZ detection status \times \sqrt{mean harmonics} \times \frac{1}{detection\_time} \times dectection duration \times topology {ranking}^{2} . \qquad Eq ( 1 )$$

19. The radial power system of claim 18, wherein the location metric value f is calculated for each sensor and a highest location metric value f indicates the sensor that is closest to and upstream from the high impedance fault event.

20. The radial power system of claim 18, wherein the plurality of sensors continually send data including current direction, current amplitude, current magnitude, and breaker status to the edge processing devices and central processor for detection of the high impedance fault event and determining the topology ranking.
